(19) United States
(12) Patent Application Publication
(10) Pub. No.: US 2016/0224061 A1
(43) Pub. Date: Aug. 4, 2016

(54) ELECTRICAL DEVICE AND METHOD OF PRODUCING THE SAME

(71) Applicant: FUJITSU LIMITED, Kawasaki-shi (JP)

(72) Inventors: Yutaka Noda, Kawasaki (JP); Yasuo Moriya, Kawasaki (JP)

(73) Assignee: FUJITSU LIMITED, Kawasaki-shi (JP)

(21) Appl. No.: 14/978,337

(22) Filed: Dec. 22, 2015

(30) Foreign Application Priority Data
Feb. 2, 2015 (JP) 2015-018237

(51) Int. Cl. G06F 1/16; H05K 13/00

(52) U.S. Cl. CPC G06F 1/1613; G06F 1/1626; G06F 1/1637; H05K 13/0023

(57) ABSTRACT

An electrical device includes a first unit including an electrode; a second unit having a hole at a position corresponding to the electrode of the first unit; a probe pin having a smaller diameter than the hole and configured to be elastically deformed, the probe pin being disposed in the hole such that a front end thereof is in contact with the electrode of the first unit; and an adhesive connecting the first unit and the second unit to each other and filling the hole so as to fix the probe pin.

### CROSS-REFERENCE TO RELATED APPLICATION

This application is based upon and claims the benefit of priority of the prior Japanese Patent Application No. 2015-018237, filed on Feb. 2, 2015, the entire contents of which are incorporated herein by reference.

### FIELD

The embodiments discussed herein are related to an electrical device and a method of producing the same.

### BACKGROUND

Mobile electrical devices such as a smartphone and a tablet terminal, which may be referred to as mobile terminals hereinafter, are widely used in these years. The mobile terminal has various functions such as a voice call function, WiFi, a Global Positioning System (GPS), a near field communication (NFC) function, and a television function, which use a wireless communication technology.

The mobile terminal includes a specific antenna for each of the functions such as a voice call function, WiFi, GPS, an NFC function, and a television function. The antenna is made of a metal thin plate, for example, and disposed on a side surface of a housing of the mobile terminal. Technologies related to this are disclosed in Japanese Laid-open Patent Publication No. 2001-22910 and Japanese Laid-open Patent Publication No. 2010-114559.

### SUMMARY

In accordance with an aspect of the embodiments, an electrical device includes a first unit including an electrode; a second unit having a hole at a position corresponding to the electrode of the first unit; a probe pin having a smaller diameter than the hole and configured to be elastically deformed, the probe pin being disposed in the hole such that a front end thereof is in contact with the electrode of the first unit; and an adhesive connecting the first unit and the second unit to each other and filling the hole so as to fix the probe pin.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

These and/or other aspects and advantages will become apparent and more readily appreciated from the following description of the embodiments, taken in conjunction with the accompanying drawing of which:

FIGS. 1A and 1B are plan views illustrating an example of an electrical device according to a first embodiment;

FIG. 2 is a cross-sectional view taken along a line II-II in FIG. 1B;

FIGS. 3A and 3B are cross-sectional views illustrating a structure of a probe pin;

FIG. 4 is a view indicating one step in a method of producing the electrical device according to the first embodiment;

FIG. 5 is a view indicating one step in the method of producing the electrical device according to the first embodiment;

FIG. 6 is a view indicating one step in the method of producing the electrical device according to the first embodiment;

FIG. 7 is a view indicating one step in the method of producing the electrical device according to the first embodiment;

FIGS. 8A and 8B are schematic cross-sectional views illustrating a first modification;

FIGS. 9A and 9B are schematic cross-sectional views illustrating a second modification;

FIG. 10 is a plan view illustrating an electrical device according to a second embodiment;

FIG. 11 is a cross-sectional view taken along a line XI-XI in FIG. 10;

FIG. 12 is a view indicating one step in a method of producing the electrical device according to the second embodiment;

FIGS. 13A and 13B are views indicating one step in the method of producing the electrical device according to the second embodiment;

FIG. 14 is a plan view illustrating an electrical device according to a third embodiment;

FIG. 15 is a cross-sectional view taken along a line XV-XV in FIG. 14;

FIG. 16 is a view indicating one step in a method of producing the electrical device according to the third embodiment;

FIG. 17 is a view indicating one step in the method of producing the electrical device according to the third embodiment; and

FIG. 18 is a view indicating one step in the method of producing the electrical device according to the third embodiment.

### DESCRIPTION OF EMBODIMENTS

Hereinafter, embodiments are described with reference to the drawings.

### First Embodiment

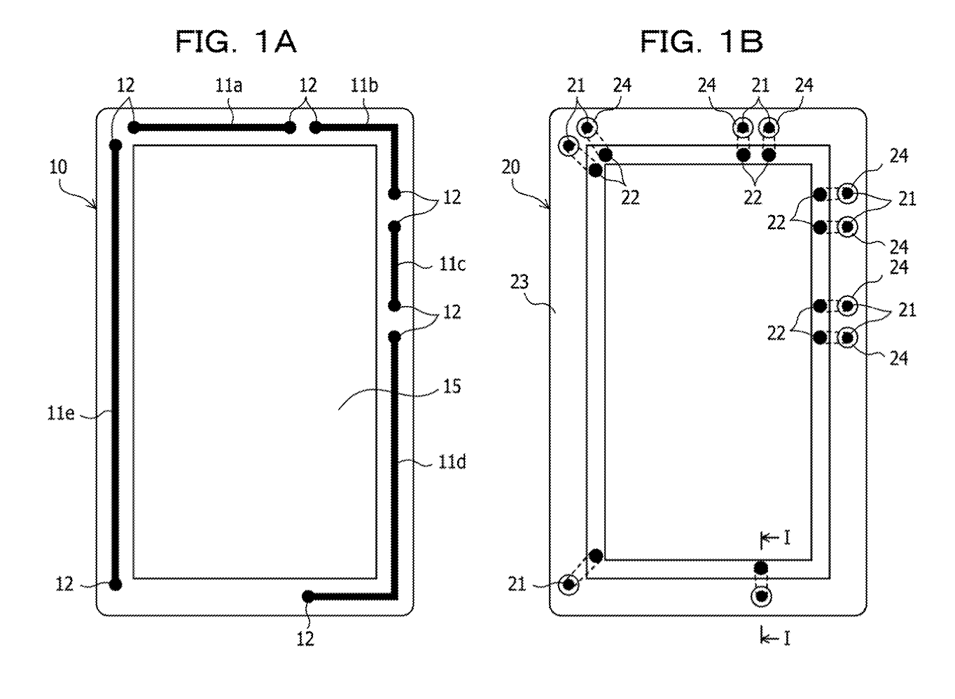

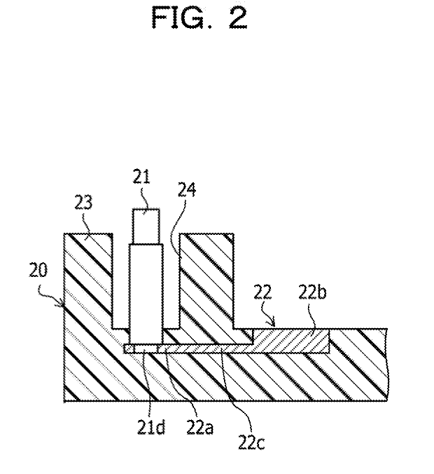

FIGS. 1A and 1B are plan views illustrating an example of an electrical device according to a first embodiment. FIG. 2 is a cross-sectional view taken along a line II-II in FIG. 1B. In this embodiment, an electrical device is a mobile terminal such as a smartphone.

FIG. 1A illustrates a display panel 10. FIG. 1B illustrates a housing 20. The mobile terminal is assembled by connecting peripheral portions of the display panel 10, which is illustrated in FIG. 1A, and the housing 20, which is illustrated in FIG. 1B, with an adhesive. The display panel 10 is an example of a first unit, and the housing 20 is an example of a second unit.

The display panel 10 is a thin plate and includes a plurality of pixels in a display area 15 for displaying characters and images, for example. As illustrated in FIG. 1A, a plurality of antennas 11a to 11e, which are metal thin plates, are disposed on the peripheral portion of the display panel 10, more specifically, on a rear surface of a portion outside the display area 15.

The length of each of the antennas 11a to 11e is determined depending on its function such as a voice call function, WiFi, GPS, an NFC function, or a television function. The antennas 11a to 11e each have a circular pad (electrode) 12 on each end thereof.

The housing 20 has a U-shaped cross section having a space in which a circuit board (not illustrated), for example, is disposed. As illustrated in FIG. 1B, the peripheral portion of the housing 20, which is referred to as a side wall 23 hereinafter, includes a plurality of recesses 24 in an upper surface thereof. The recesses 24 are located at positions corresponding to the pads 12 on the display panel 10.

As illustrated in FIG. 2, a probe pin 21 is disposed in each recess 24. The probe pin 21 includes a coil spring therein, which is described later, and elastically stretches (deforms) in an axial direction thereof. The probe pin 21 has a smaller diameter than the recess 24. The probe pin 21 and the inner surface of the recess 24 define a space to be filled with an adhesive, which is described later.

The diameter of the probe pin 21 and the diameter of the recess 24 may be suitably determined. The diameter of the probe pin 21 may be in a range of 0.2 mm to 2 mm, and the diameter of the recess 24 may be in a range of 1.2 mm to 6 mm.

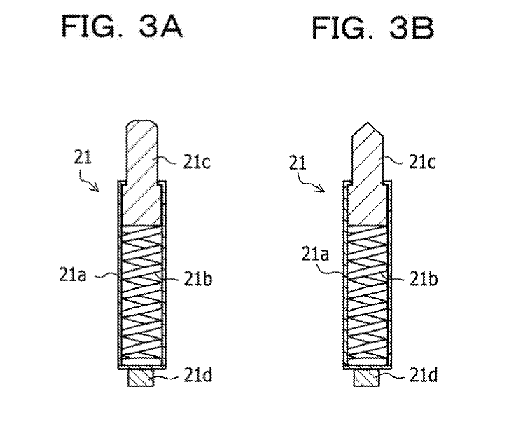

FIG. 3A is a cross-sectional view illustrating a structure of the probe pin 21. As illustrated in FIG. 3A, the probe pin 21 includes a cylindrical portion 21a, a coil spring 21b, a contact portion 21c, and an insertion portion 21d. The probe pin 21 is made of metal.

The cylindrical portion 21a has a cylindrical shape, and the coil spring 21b is disposed in the cylindrical portion 21a. The contact portion 21c has a bar shape. The contact portion 21c has a lower portion positioned in the cylindrical portion 21a and an upper portion protruding upward from the cylindrical portion 21a. The contact portion 21c is biased upward by an elastic force of the coil spring 21b.

The insertion portion 21d is a protrusion extending from the lower end of the cylindrical portion 21a. As illustrated in FIG. 2, a probe pin connecting portion 22a of a connection terminal 22 is disposed on a bottom of the recess 24. When the insertion portion 21d is inserted into a hole in the probe pin connecting portion 22a, the probe pin 21 and the connection terminal 22 are electrically and mechanically connected to each other.

The probe pin 21 may have a flat front end as illustrated in FIG. 3A or may have a pointed front end as illustrated in FIG. 3B.

As illustrated in FIG. 2, the connection terminal 22 includes the probe pin connecting portion 22a, which is disposed on the bottom of the hole 24, a pad 22b, which is disposed inwardly from the side wall 23 and connected to the circuit board, and a connection 22c, which extends between the probe pin connecting portion 22a and the pad 22b.

The probe pin connecting portion 22a, the pad 22b, and the connection 22c are formed of metal as one component. The connection terminal 22 is integrated with the housing 20 by an insert molding process, for example.

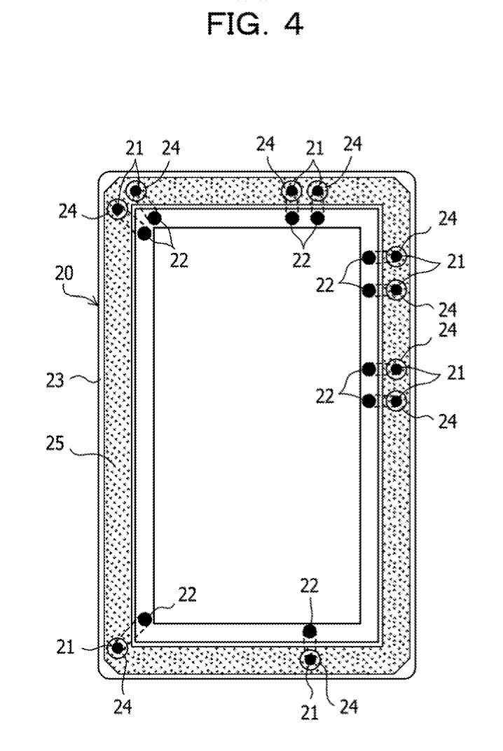

Hereinafter, a method of producing an electrical device (mobile terminal) in the first embodiment is described with reference to FIG. 1, and FIG. 4 to FIG. 7.

The display panel 10 and the housing 20 illustrated in FIGS. 1A and 1B are formed first. The antennas 11a to 11e and the pads 12, which are metal thin films, are formed on the peripheral portion of the display panel 10.

A copper foil coated film is punched out or etched to form antenna blanks and pad blanks, for example. Then, the obtained blanks are attached to the peripheral portions of the display panel 10 to form the antennas 11a to 11e and the pads 12. Alternatively, a conductive paste may be printed on the peripheral portion of the display panel 10 to form the antenna blanks and the pad blanks. Then, the obtained blanks may be plated with copper to form the antennas 11a to 11e and the pads 12.

The housing 20 is formed by the insert molding process, for example, in which a resin material and the connection terminal 22 are integrated. A circuit board is disposed in the housing 20 such that a terminal of the circuit board is in contact with the connection terminal 22. Thus, the circuit board and the housing 20 are electrically connected to each other.

Then, as illustrated in a plan view of FIG. 4, an adhesive 25 is applied to an upper surface of the side wall 23 of the housing 20. At the same time, the hole 24 is filled with the adhesive 25. The type of the adhesive 25 is not limited. An adhesive that contracts in volume as curing thereof proceeds, which is referred to as a cure shrinkable adhesive hereinafter, is preferably used. The cure shrinkable adhesive preferably has a shrinkage rate, or a shrinkage rate in a thickness direction, in a range of about 3% to about 8%.

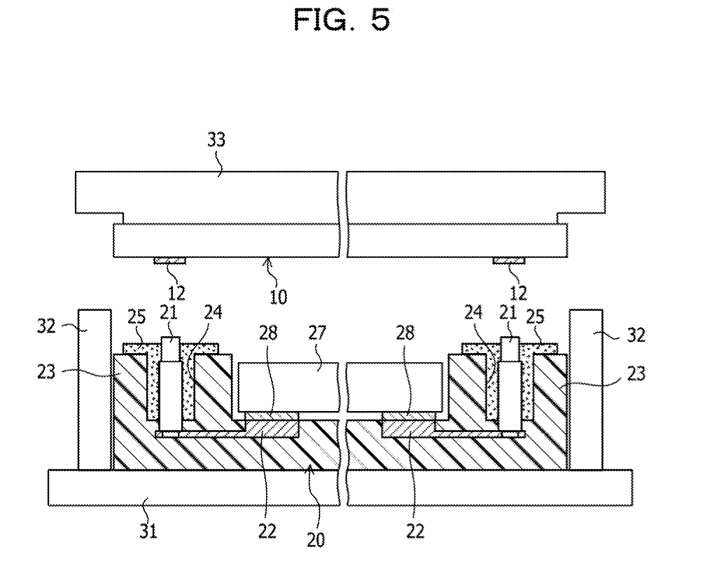

Then, as illustrated in FIG. 5, the housing 20 is disposed in a housing fixture jig 31. The housing fixture jig 31 includes stop blocks 32 having a predetermined height at positions around the housing 20.

The reference numeral 27 in FIG. 5 denotes a circuit board disposed in the housing 20. The circuit board 27 includes an electronic circuit for activation of the display panel 10. The reference numeral 28 in FIG. 5 denotes a terminal of the circuit board 27.

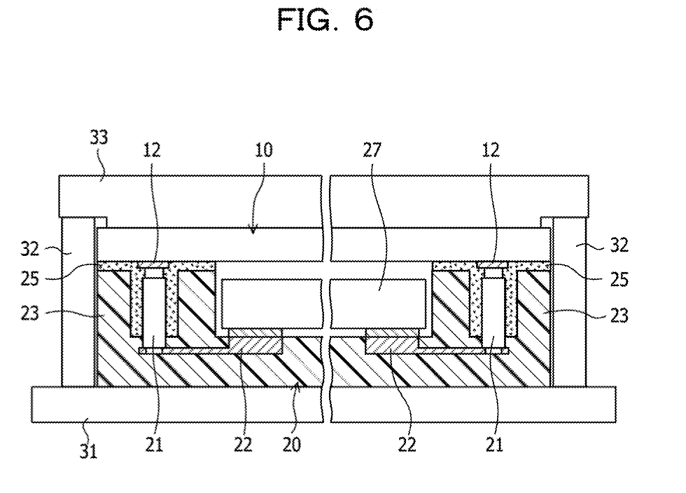

Then, the display panel 10 is sucked by a suction tool 33 of a vacuum suction transport machine, for example, and disposed above the housing 20. Then, as illustrated in FIG. 6, the suction tool 33 is moved down until the suction tool 33 comes in contact with the stop block 32. The distance between the upper surface of the side wall 23 and the display panel 10 is made substantially constant by the contact between the suction tool 33 and the stop blocks 32. Thus, an adhesive layer having a uniform thickness is obtained.

In the specification, the adhesive positioned between the display panel 10 and the side wall 23 is referred to as an adhesive layer. The thickness of the adhesive layer is in the range of 0.2 mm to 0.4 mm, for example.

Then, the adhesive 25 is cured. The contact portion 21c and the pad 12 are kept in contact with each other under a substantially constant pressure due to the elastic force of the coil spring 21b until the adhesive 25 is cured. Then, the contact portion 21c and the pad 12 are fixed to each other due to the curing of the adhesive 25 with the contact pressure being maintained. Since the cured adhesive 25 fixes the contact portion 21c, the probe pin 21 loses its stretchability (elasticity). In other words, the adhesive 25 attached to the probe pin 21 fixes the shape of the probe pin 21.

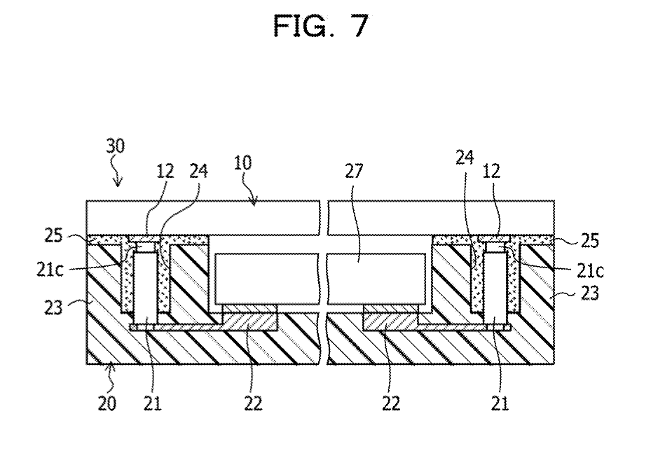

Then, an electrical device (mobile terminal) including the housing 20 and the display panel 10 connected together is removed from the housing fixture jig 31 after the adhesive 25 is sufficiently cured. FIG. 7 illustrates a cross-sectional view of the electrical device 30 removed from the housing fixture jig 31. The electrical device 30 is produced in this way.

As described above, in this embodiment, since the front end (contact portion 21c) of the probe pin 21 comes in elastic contact with the pad 12, the probe pin 21 reliably comes in contact with the pad 12 even if the adhesive layer has a non-uniform thickness.

In addition, in this embodiment, since the stretchability of the probe pin 21 is lost when the adhesive 25 is cured, creep deformation of the adhesive layer does not occur even when the electrical device is used for a long period of time. Thus, the connection obtained by the adhesive 25 has long-term reliability.

In this embodiment, the probe pin 21 and the connection terminal 22 are electrically and mechanically connected when the insertion portion 21d of the probe pin 21 is inserted into the hole of the connection terminal 22. However, the probe pin 21 and the connection terminal 22 may be connected by soldering or with a conductive adhesive, for example, or may be connected with a screw or by welding.

First Modification

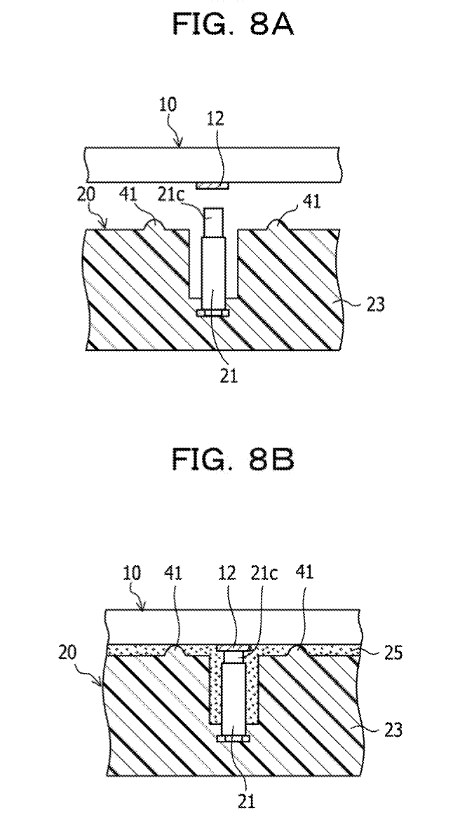

FIGS. 8A and 8B are schematic cross-sectional views illustrating an electrical device according to a first modification. In the first modification, the side wall of the housing 20 includes protrusions, which are not included in the first embodiment, on the upper surface thereof so as to limit the thickness of the adhesive layer. The other configurations are substantially identical to those in the first embodiment and are not described in detail. In FIGS. 8A and 8B, components identical to those in FIG. 2 and FIG. 7 are assigned the same reference numerals as those in FIG. 2 and FIG. 7.

As illustrated in FIG. 8A, in the first modification, protrusions 41 are disposed at predetermined positions on the upper surface of the side wall 23 of the housing 20. As illustrated in FIG. 8B, when the display panel 10 is connected to the housing 20 with the adhesive 25, the display panel 10 is brought into contact with the top of each protrusion 41. This enables the adhesive layer to have a uniform thickness. The height of the protrusion 41 may be suitably determined. In this modification, the height of the protrusion 41 is in a range of 0.2 mm to 0.4 mm. The height of the protrusion 41 corresponds to the thickness of the adhesive layer.

In the first modification, since the thickness of the adhesive layer is made uniform by the contact between the protrusions 41 and the display panel 10, the housing fixture jig 31 including the stop blocks 32 as illustrated in FIG. 5 is unnecessary. In addition, the adhesive layer has more uniform thickness.

In the above-described modification, the housing 20 includes the protrusions 41. However, the display panel 10 may include the protrusions 41.

Second Modification

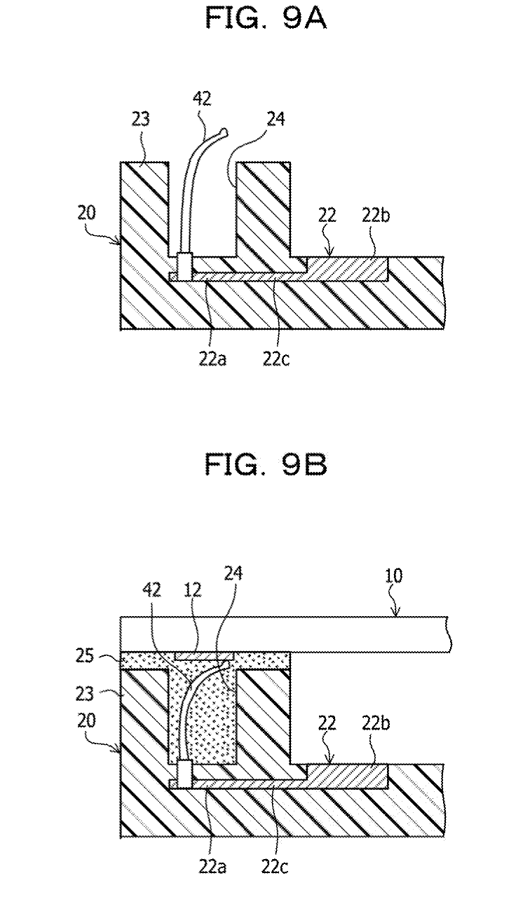

FIGS. 9A and 9B are schematic cross-sectional views illustrating a second modification. In FIGS. 9A and 9B, components identical to those in FIG. 2 are assigned the same reference numerals as those in FIG. 2.

In the second modification, as illustrated in FIG. 9A, a plate spring is used as the probe pin 42. The lower end of the probe pin 42 is connected to the connection terminal 22, and the upper end thereof protrudes upward a little from the side wall 23 of the housing 20.

As illustrated in FIG. 9B, when the display panel 10 and the housing 20 are connected with the adhesive 25, the pad 12 of the display panel 10 presses the probe pin 42 such that the probe pin 42 elastically curves or bends. Thus, the front end of the probe pin 42 and the pad 12 are in contact with each other under a substantially constant pressure.

Then, when the adhesive 25 is cured, the adhesive 25 in the hole 24 fixes the shape of the probe pin 42, and thus the elasticity of the probe pin 42 is lost.

In the second modification, the advantages identical to those in the first embodiment are obtained.

### Second Embodiment

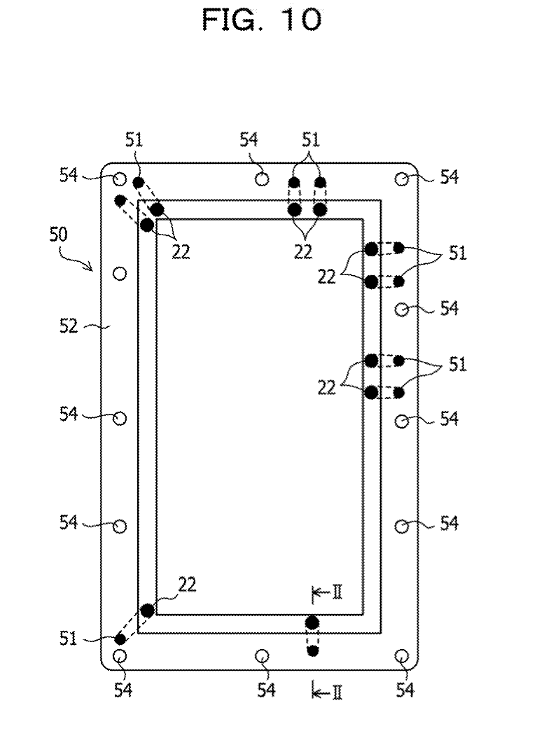

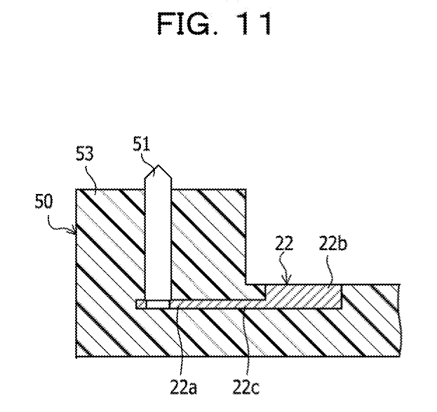

FIG. 10 is a plan view illustrating a housing 50 of an electrical device of a second embodiment. FIG. 11 is a cross-sectional view taken along a line XI-XI in FIG. 10. In the second embodiment, the electrical device is a mobile terminal such as a smartphone as in the first embodiment. Components identical to those in the first embodiment are not described.

The housing 50 has a U-shaped cross section having a space in which a circuit board (not illustrated), for example, is disposed. Probe pins 51 and protrusions 54, which regulate the thickness of the adhesive layer, are disposed at predetermined positions on a side wall 53 of the housing 50.

The probe pin 51 of this embodiment is a bar and does not have stretchability, although the probe pin 21 in the first embodiment has stretchability (elasticity). In addition, although the housing 20 in the first embodiment has the space (holes 24) to be filled with the adhesive around the probe pin 21, the housing 50 in this embodiment does not have such a space.

Only a front end portion of the probe pin 51 protrudes upward from the side wall 53, and the remaining portion is in the side wall 53. The front end portion of the probe pin 51 protrudes by an amount substantially identical to or more than the value obtained by subtracting the thickness of the pad 12 from the height of the protrusion 54.

As illustrated in FIG. 11, the probe pin 51 has a pointed front end. The lower end of the probe pin 51 is connected to the connection terminal 22.

The probe pin 51 and the connection terminal 22 may be integrally formed. As in the first embodiment, the probe pin 51 and the connection terminal 22 may be electrically and mechanically connected by the insertion of the lower end portion of the probe pin 51 into the hole of the probe pin connecting portion 22a of the connection terminal 22.

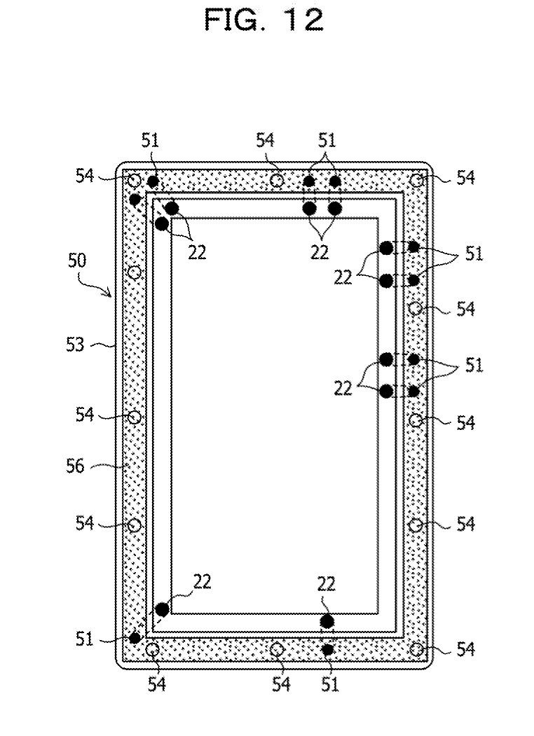

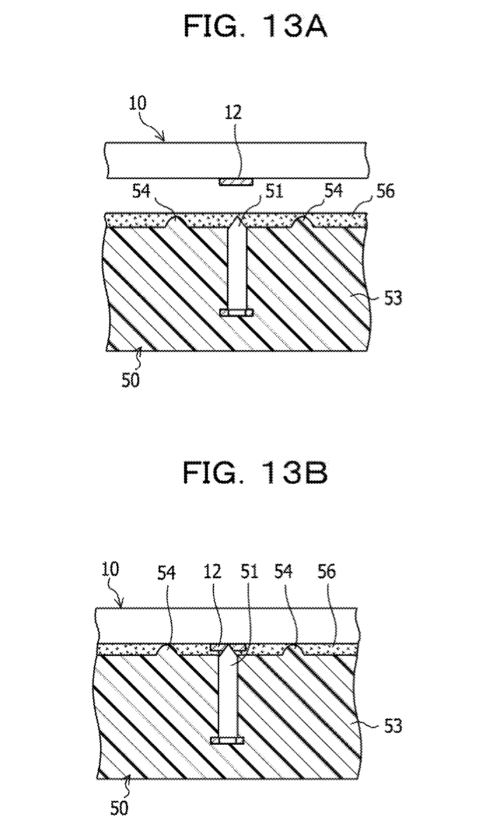

Hereinafter, a method of producing the electrical device (mobile terminal) of the second embodiment is described with reference to FIG. 12 and FIGS. 13A and 13B.

As illustrated in a plan view of FIG. 12, an adhesive 56 is applied to an upper surface of the side wall 53 of the housing 50. A cure shrinkable adhesive, which contracts in volume as curing thereof proceeds, is preferably used as the adhesive 56, although the type of the adhesive 56 is not limited.

Then, the display panel 10 is sucked by a suction tool of a vacuum suction transport machine, for example, and disposed above the housing 50 as illustrated in FIG. 13A. The suction tool is moved down until the display panel 10 comes in contact with the protrusions 54 as illustrated in FIG. 13B.

This enables the front end of the probe pin 51 to stick into the pad 12, establishing an electrical connection between the probe pin 51 and the pad 12.

Then, the adhesive 56 is cured to maintain the connection between the probe pin 51 and the pad 12. A force that draws the display panel 10 toward the housing 50 is generated by the cure shrinkable adhesive used as the adhesive 56. Thus, the probe pin 51 and the pad 12 are reliably connected, further improving the reliability of the electrical connection. The electrical device according to the second embodiment is produced in this way.

As described above, in this embodiment, the thickness of the adhesive layer is made uniform by contacting the display panel 10 with the protrusions 54 on the side wall 53 of the housing 50. This reduces unevenness in the thickness of the adhesive layer, leading to a reliable connection between the probe pin 51 and the pad 12.

In this embodiment, the probe pin 51 has a pointed front end so as to stick into the pad 12. With this configuration, the electrical connection between the probe pin 51 and the pad 12 is more reliably established.

In addition, since the probe pin 51 in this embodiment does not have elasticity, creep deformation does not occur in the adhesive layer even when the electrical device is used for a long period of time.

### Third Embodiment

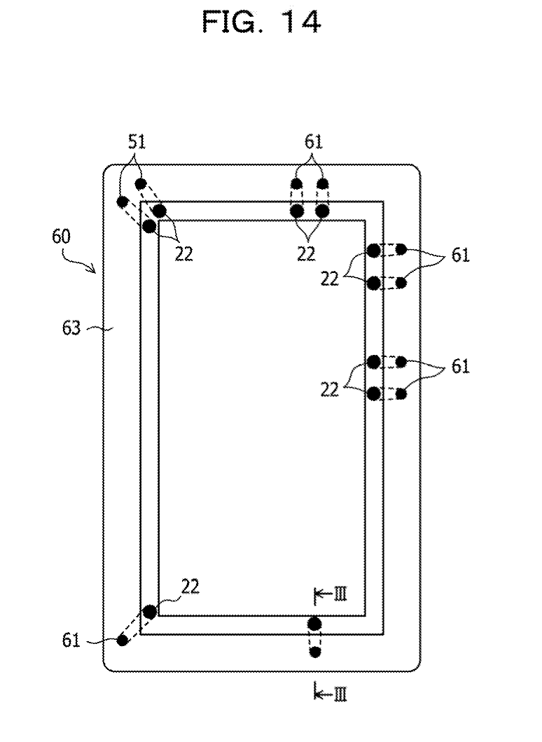

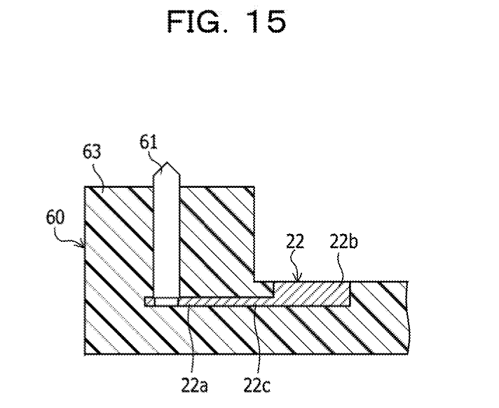

FIG. 14 is a plan view illustrating a housing 60 of an electrical device according to a third embodiment. FIG. 15 is a cross-sectional view taken along a line XV-XV in FIG. 14. In the third embodiment, the electrical device is a mobile terminal such as a smartphone as in the above-described embodiments. Components identical to those in the first embodiment are not described.

The housing 60 has a U-shaped cross section having a space in which a circuit board (not illustrated), for example, is disposed. Probe pins 61 are disposed at predetermined positions on the side wall 63 of the housing 60. The probe pin 61 of this embodiment is a bar and does not have stretchability as in the second embodiment. In addition, as in the second embodiment, the housing 60 in the third embodiment does not have a space to be filled with the adhesive around the probe pin 61.

Only a front end portion of the probe pin 61 protrudes upward from the side wall 63, and the remaining portion is in the side wall 63. The length of the front end portion of the probe pin 61 protruding from the side wall 63 is determined depending on a preferable thickness of the adhesive layer. The probe pin 61 has a pointed front end, and the lower end thereof is connected to the connection terminal 22.

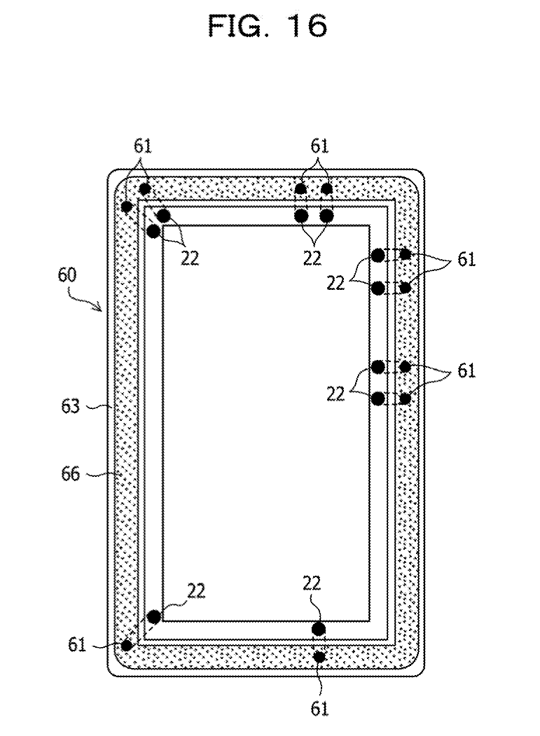

Hereinafter, a method of producing the electrical device (mobile terminal) according to the third embodiment is described with reference to FIG. 16 to FIG. 18.

As illustrated in a plan view of FIG. 16, an adhesive 66 is applied to an upper surface of the side wall 63 of the housing 60. A cure shrinkable adhesive, which contracts in volume as curing thereof proceeds, is preferably used as the adhesive 66. However, if a thermosetting shrinkable adhesive, which is cured by heat, is used, the adhesive needs to be heated at a temperature of 80° C. or more so as to be cured. This may deteriorate characteristics of the display panel 10 and characteristics of a semiconductor, for example, mounted in the circuit board.

In view of the above, in the third embodiment, a cure shrinkable adhesive other than the thermosetting shrinkable adhesive, which is referred to as a non-thermosetting shrinkable adhesive hereinafter, is used. Examples of the non-thermosetting shrinkable adhesive include a one-component epoxy adhesive, a two-component epoxy adhesive, a moisture curing silicone adhesive, a reactive urethane adhesive, and a two-component acrylic adhesive.

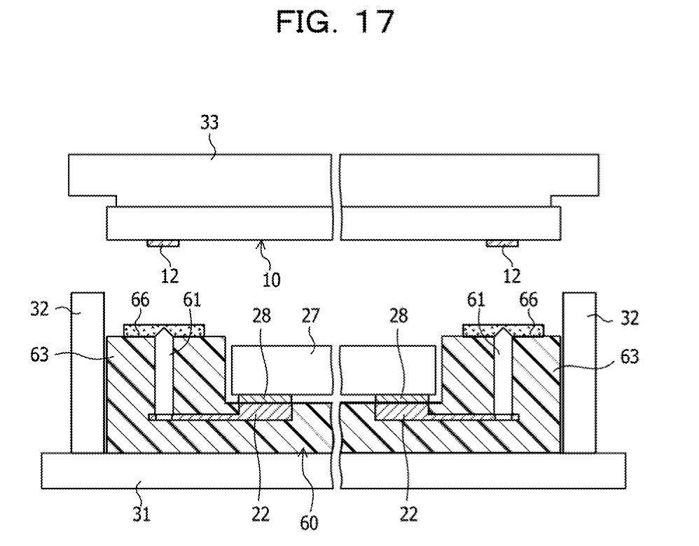

Then, as illustrated in FIG. 17, the housing 60 is placed in the housing fixture jig 31. The housing fixture jig 31 includes the stop blocks 32 having a predetermined height at positions around the housing 60.

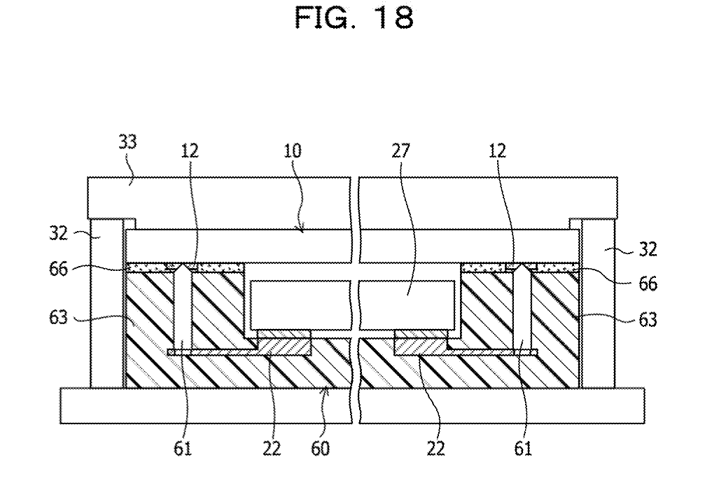

Then, the display panel 10 is sucked by the suction tool 33 of the vacuum suction transport machine, for example, and disposed above the housing 60. The suction tool 33 is moved down until the suction tool 33 comes in contact with the stop block 32 as illustrated in FIG. 18.

As described above, the distance between the upper surface of the side wall 63 and the display panel 10 is made substantially constant by the contact between the suction tool 33 and the stop blocks 32. Thus, the adhesive layer has a uniform thickness. In addition, the probe pin 61 has the pointed front end so as to stick into the pad 12. With this configuration, the electrical connection between the probe pin 61 and the pad 12 is reliably established.

Then, the adhesive 66 is cured. The electrical device according to the third embodiment is produced in this way.

As described above, in the third embodiment, the cure shrinkable adhesive is used as the adhesive 66. With this configuration, the display panel 10 comes closer to the housing 60 as the curing of the adhesive 66 proceeds even if the probe pin 61 and the pad 12 are not sufficiently in contact with each other immediately after the connection between the display panel 10 and the housing 60 with the adhesive 66. Thus, the probe pin 61 and the pad 12 sufficiently come in contact with each other, and the electrical connection between the probe pin 61 and the pad 12 is established.

In the third embodiment, the probe pin 61 has a pointed front end so as to stick into the pad 12. With this configuration, the electrical connection between the probe pin 61 and the pad 12 is more reliably established.

In addition, since the probe pin 61 in this embodiment does not have elasticity, creep deformation does not occur in the adhesive layer even when the electrical device is used for a long period of time.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that various changes, substitutions, and alterations could be made hereto without departing from the spirit and scope of the invention.

What is claimed is:

1. An electrical device comprising:
a first unit including an electrode;
a second unit having a hole at a position corresponding to the electrode of the first unit;
a probe pin having a smaller diameter than the hole and configured to be elastically deformed, the probe pin being disposed in the hole such that a front end thereof is in contact with the electrode of the first unit; and
an adhesive connecting the first unit and the second unit to each other and filling the hole so as to fix the probe pin.

2. The electrical device according to claim 1, further comprising:
a protrusion on at least one of the first unit and the second unit, the protrusion being in contact with the other of the first unit and the second unit and regulating a thickness of a layer of the adhesive.

3. The electrical device according to claim 1,
wherein the adhesive is a cure shrinkable adhesive that contracts in volume as curing thereof proceeds.

4. The electrical device according to claim 1,
wherein the probe pin has a pointed front end.

5. The electrical device according to claim 1,
wherein the probe pin includes a coil spring and a contact portion configured to be biased by the coil spring so as to be in contact with the electrode.

6. The electrical device according to claim 1,
wherein the probe pin is a plate spring.

7. The electrical device according to claim 1, further comprising:
a circuit board in the second unit,
wherein the first unit is a display panel configured to be activated by the circuit board.

8. The electrical device according to claim 7,
wherein the electrode of the first unit is connected to an antenna.

9. A method of producing an electrical device comprising:
forming a first unit including an electrode;
forming a second unit having a hole at a position corresponding to the electrode and including a probe pin disposed in the hole, the probe pin having a smaller diameter than the hole and configured to be elastically deformed;
arranging the first unit and the second unit such that an adhesive is disposed therebetween;
allowing the adhesive to fill the hole;
bringing a front end of the probe pin into contact with the electrode in an elastic manner; and
curing the adhesive so as to fix the probe pin with the adhesive attached to the probe pin.

10. A method of producing an electrical device comprising:
forming a first unit including an electrode and a second unit including a plurality of protrusions and a probe pin having a pointed front end;
bringing the plurality of protrusions into contact with the first unit; and
allowing the front end of the probe pin to stick into the electrode and connecting the first unit and the second unit with an adhesive.

11. The method of producing the electrical device according to claim 10, further comprising providing a cure shrinkable adhesive as the adhesive that contracts in volume as curing thereof proceeds.

12. A method of producing an electrical device comprising:
forming a first unit including an electrode and a second unit including a probe pin having a pointed front end; and
allowing the front end of the probe pin to stick into the electrode and connecting the first unit and the second unit with a cure shrinkable adhesive that contracts in volume as curing thereof proceeds.
